(19) United States
(12) Patent Application Publication
(10) Pub. No.: US 2004/0117722 A1
(43) Pub. Date: Jun. 17, 2004

(54) Performance of communication systems using forward error correction

(75) Inventor: Atsushi Harada, Yamato-shi (JP)

Correspondence Address: David R. Irvin, IBM Corporation, T81/503, PO Box 12195, Research Triangle Park, NC, 27709, US

(73) Assignee: International Business Machines Corporation, Armonk, NY

(21) Appl. No.: 10/715,579

(22) Filed: Nov. 18, 2003

(30) Foreign Application Priority Data
Nov. 28, 2002 (JP) 2001-345230

(51) Int. Cl. G06F 11/00; H03M 13/00

(52) U.S. Cl. 714/800

(57) ABSTRACT

To increase the probability of transmission success in data communication systems using forward error correction (FEC), a data file of original data to be transmitted is divided into clusters of blocks of data. Convolution data acquired from another cluster is added to original data of the cluster for encoding to generate parity data. Part of the parity data is added to the original data, and the resultant is transmitted over the network.

### FIELD OF THE INVENTION

The present invention relates to the field of data communication in a network, and more specifically to a technique for improving the reliability of data communication systems with forward error correcting codes.

### BACKGROUND

As computer networks such as the Internet have become popular, network integrity, i.e., freedom from transmission error, has increasingly become an important consideration.

One way to minimize the effects of transmission error is to use an automatic repeat request (ARQ) protocol. A receiving terminal automatically requests data retransmission of data sent by a transmitting terminal when that data has been lost or flawed in transit by channel errors. Here, the case of corruption or loss of data may be referred to as a “loss.” Another way to protect against channel errors is to use a forward error correction (FEC) code which provides added redundancy that may be used to reconstruct bits that are corrupted by channel error. Protocols and codes are also used which combine both ARQ and FEC. Many ARQ protocols are premised on two-way communication, which enables a receiving terminal to explicitly request retransmissions, whereas FEC codes may be used when only one-way communication is available.

One form of FEC involves an erasure code that allows lost data to be restored from data correctly received (See, for example, L. Rizzo, “Effective erasure codes for reliable computer communication protocols”, ACM Computer Communication Review, April 1997). A theoretical explanation of erasure codes is given by Johannes Blomer, Malik Kalfane, Richard Karp, Marek Karpinski, Michael Luby, David Zuckerman, “An XOR-Based Erasure-Resilient Coding Scheme”, Technical Report, International Computer Science Institute, Berkeley, Calif., 1995; available on-line at http://citeseer.nj.nec.com/84162.html With this approach, a transmitter adds parity data to original data to be transmitted. A receiver extracts the original data from the received transmission data. Within limits, the original data can be recovered from the received data even in the presence of channel errors. Another example of using an erasure code is given by U.S. Pat. No. 6,012,159, “Method and system for error-free data transfer,” to Fischer, et al., which is hereby incorporated herein by reference in its entirety.

FIG. 11 is a diagram illustrating a data communication method according to the aforementioned US patent. First, a data file (original data) is divided into clusters. As shown in FIG. 11, the data file is divided into eight clusters, each of which has k blocks of data (k has the value 6 in the example shown). The term “cluster” refers to a unit for dividing original data to be transmitted. In the following description, the term “cluster” may refer to original data or to a combination of original data and parity data. Each of the k blocks of data may be, for example, 1 Kbyte, 8 Kbyte, and so forth. Next, the transmitter 1101 generates (encodes) t blocks of parity data (in the shown example, four blocks) from the k blocks of original data, and transmits the parity data with the original data (i.e., a data string made of k+t blocks of data) for each cluster. The receiver 1102 receives the data string. If part of the data string is lost during transmission, the receiver 1102 restores (decodes) the original k blocks of data of the corresponding cluster. In the example shown in FIG. 11, if at least six blocks of original data and/or parity data are received, i.e., if not more than four blocks are lost, the original data can be restored by the receiver.

According to the method of the aforementioned US patent, parity data is independently generated from original data for each cluster. When original data is restored for each cluster, the original data is restored only from a data string that includes parity data for that cluster. That is to say, according to this art, k or more blocks of data must be received for each cluster for successful data reception.

However, the above-mentioned conventional data communication method with an erasure code cannot restore the original data when more than t blocks are lost from the k+t blocks, where the number of blocks of original data of a cluster is k. Furthermore, all the receivers of a multipoint system have to receive the data successfully. Thus, the probability of distribution success decreases as the number of receivers and clusters increases.

The processing cost of a retransmission will now be considered. A request for retransmission is made by the receiver to the transmitter. In the case of a uni-cast distribution, which individually transmits data to each receiver, the processing cost of retransmission is proportional to the number of receivers requesting retransmission, so that the processing cost of the retransmission is generally lower than the processing cost of the initial distribution. On the other hand, in the case of a simulcast such as a broadcast or multicast, the processing cost of retransmission does not depend on the number of receivers, so that the processing cost of the retransmission is the same as the processing cost of the initial distribution. Therefore, a high probability of distribution success is required, especially in the case of a simulcast.

In a conventional data communication method as described in the aforementioned US patent, the number of blocks of parity data t and/or the number of blocks of original data k of a cluster may be increased in order to improve the probability of distribution success. However, as the proportion of parity data (redundancy) increases, the volume of data to be transmitted and transmission time increase. Also, as the number k of blocks of original data increases, the computational requirements of encoding and decoding increase significantly.

### SUMMARY

An object of the present invention is to improve the reliability of data communication by increasing the probability of distribution success in data a communication system with FEC. Another object of the present invention is to reduce the level of redundancy needed in a data communication system with FEC.

In view of these and other objects, the present invention includes a data processing method comprising the steps of dividing a data file of original data into clusters of the same size, each of which has k blocks of data; generating t+s blocks of parity data from the k blocks of original data and s blocks of convolution data for encoding; generating transmission data of k+t blocks of data by adding t blocks of parity data to the original data; and transmitting the transmission data to another terminal.

The convolution data for one cluster is determined using data of another cluster. More specifically, s blocks of parity data generated for the cluster immediately before the given cluster are used as convolution data of the given cluster, where “before” refers to the encoding order of clusters. In order to prevent a decrease in the probability of reception success of the last cluster of the sequence, all of the generated t+s blocks of parity data may be especially transmitted for the last cluster. Alternatively, transmission data may be generated by adding t′ blocks of data, where t′>t, from t+s blocks of parity data to the original data.

The present invention also includes a data processing method comprising the steps of dividing a data file of original data into clusters; generating parity data for a given cluster using information on another cluster by encoding the original data of the given cluster and convolution data of the other cluster, generating transmission data by adding the parity data to the original data; and transmitting the transmission data to another terminal.

To generate parity data for the given cluster, part of the parity data of the other cluster is added to the original data and encoded. As a result, the generated parity data includes information on the parity data of the other cluster.

The present invention also includes a data processing method for receiving transmission data generated in the above-mentioned manner, comprising the steps of receiving a data string including original data and parity data; if any data is lost in a given cluster during communication, decoding data remaining in the given cluster and restoring the original data and convolution data added to the original data for generating the parity data; unless the number of blocks of data of the given cluster is sufficient to enable the FEC to restore the original data and the convolution data lost during communication, complementing and decoding data of the given cluster on the basis of restored data of at least one other cluster and restoring the original data and the convolution data; and generating a data file by concatenating the original data of the received or restored cluster.

For complementing data of a cluster, data can be used that is acquired by encoding original data and convolution data restored in the cluster immediately before the cluster and/or the convolution data restored in the cluster immediately after in the encoding order.

The present invention also includes a communication system wherein a transmitting terminal divides a data file of original data into clusters, generates parity data for a given cluster using data of another cluster, adds the parity data to the original data, and transmits the resulting transmission data to a receiving terminal. The receiving terminal receives the transmission data and restores the original data for each cluster if part of the transmission data is lost during communication. Unless the number of blocks of data of transmission data of a received cluster is sufficient to enable the FEC to restore the original data lost during communication, the original data is restored by complementing data of the received cluster using restored data of at least one other cluster.

More specifically, a data transmitter of a transmitting terminal may include a file storage unit for storing a data file of original data; a transmission data generation unit for reading the data file of the original data transmitted from the file storage unit and diving it into clusters, generating parity data for a given cluster using data of another cluster (the cluster immediately before in an encoding order), and generating transmission data including the parity data and the original data; and a transmission control unit for transmitting the transmission data generated by the transmission data generation unit.

The data receiver of a receiving terminal device may include a reception control unit for receiving a data string including original data and parity data; a data restoring unit which, if any data is lost in a given cluster during communication, decodes data remaining in the given cluster and restores the original data and convolution data added to the original data for generating the parity data and which, unless the number of blocks of data of the given cluster is sufficient to enable the FEC to restore the original data and the convolution data lost during communication, complements and decodes the data of the given cluster on the basis of restored data of at least one other cluster to restore the original data and the convolution data; and a file storage unit for storing a data file acquired by concatenating original data of each of the received or restored cluster.

The present invention also includes a program for enabling a computer to execute a process corresponding to each step of the above-mentioned data processing method by controlling the computer, or a program for enabling a computer to function as the above-mentioned data transmitter or data receiver. The program can be provided by storing and delivering on a magnetic disc, an optical disc, semiconductor memory, or other storage media, or by distributing over a network.

### BRIEF DESCRIPTION OF THE DRAWINGS

FIG. 1 is a diagram showing an outline of a network system.

FIG. 2 is a diagram of a hardware configuration of a computer suitable for implementation of the invention.

FIG. 3 is a diagram showing a functional configuration of a transmitting terminal.

FIG. 4 is a diagram illustrating a method for generating parity data.

FIG. 5 is a flowchart illustrating a method of transmitting data.

FIG. 6 is a diagram showing a functional configuration of a receiving terminal.

FIGS. 7A and 7B illustrate a decoding method.

FIG. 8 is a diagram showing how data may be complemented by using a decoded cluster.

FIG. 9 is a flowchart showing a method of receiving data.

FIG. 10 is a flowchart showing a method of receiving data by a receiving terminal.

FIG. 11 is a diagram illustrating a data communication method according to the prior art.

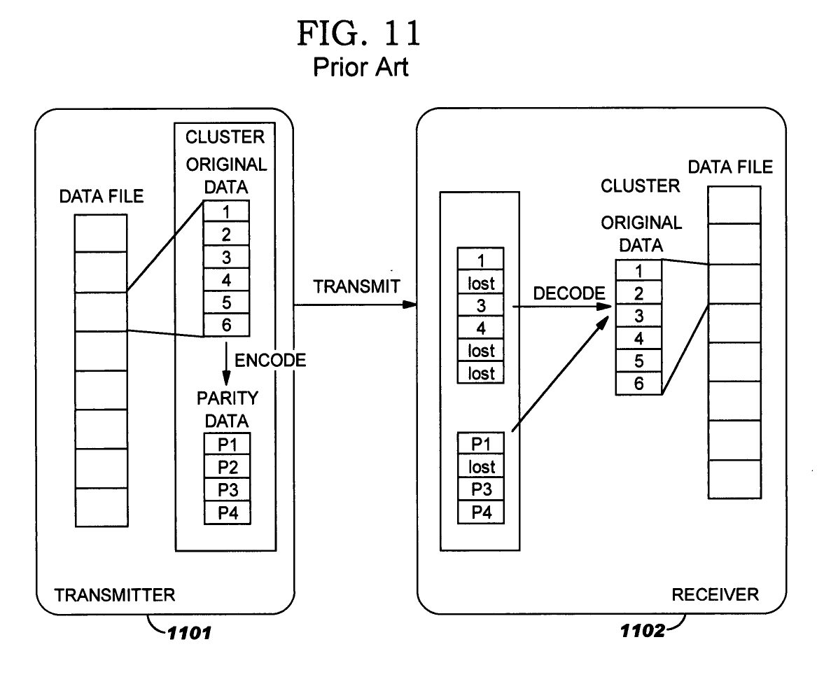

### DETAILED DESCRIPTION

The present invention will be described in detail with reference to the attached drawings.

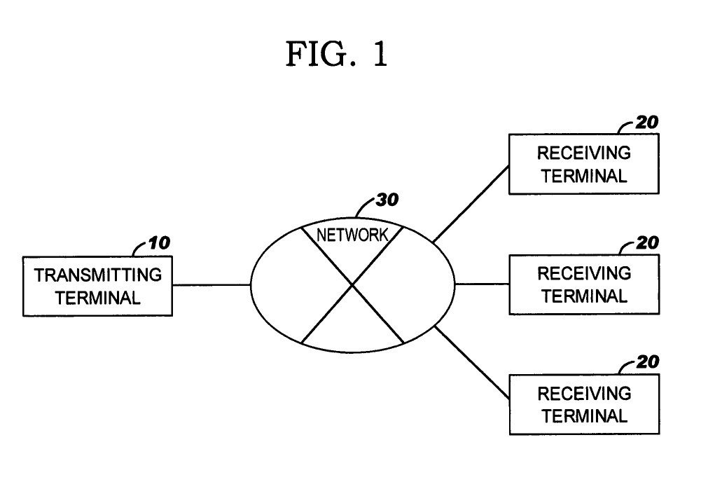

FIG. 1 is a diagram showing an outline of a suitable network system, which may be configured by connecting a transmitting terminal 10 and a receiving terminal 20 to a network 30 such as the Internet. Transmitting terminal 10 and receiving terminal 20 may be implemented using a computer, a PDA (Personal Digital Assistant), a cellular phone, or other information communication device (a terminal) with provision for exchanging data by packet communication via the network 30. The transmitting terminal 10 and receiving terminal 20 refer to, respectively, a terminal that may be used by a user to transmit given data and a terminal that receives the data. As shown in the figure, data can not only be transmitted to each of a plurality of receiving terminals 20 separately, but can also be transmitted to all of a plurality of receiving terminals 20 by multi-destination distribution.

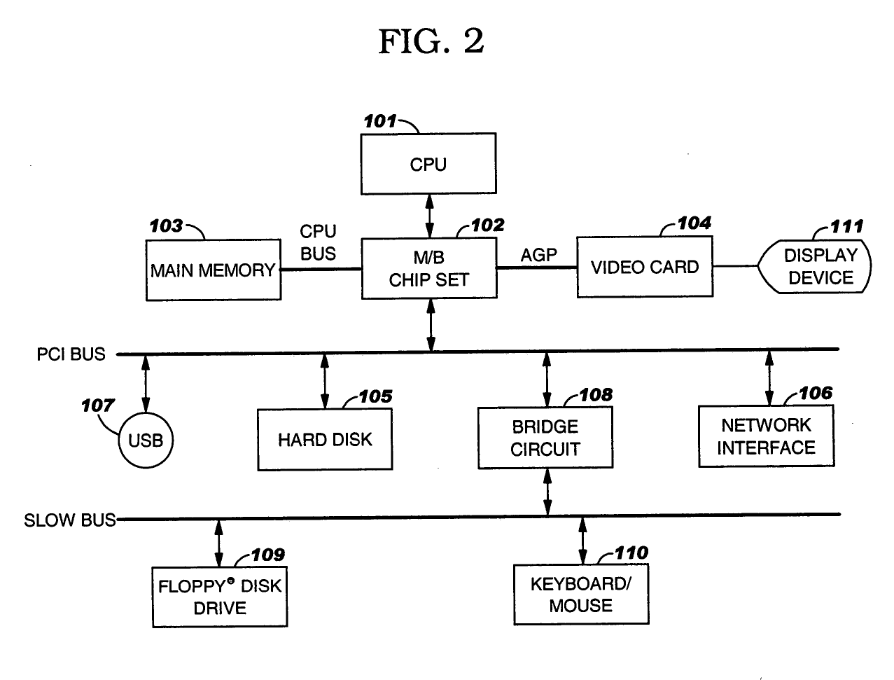

FIG. 2 is a diagram typifying an exemplary hardware configuration of a computer that is suitable for implementing the transmitting terminal 10 and the receiving terminal 20. The exemplary computer shown in FIG. 2 includes CPU (Central Processing Unit) 101 of an arithmetic means, main memory 103 connected to CPU 101 via M/B (mother board) chip set 102 and CPU bus, video card 104 connected to CPU 101 via also M/B chip set 102 and AGP (Accelerated Graphics Port), hard disk 105, network interface 106 and USB port 107 connected to M/B chip set 102 via PCI (Peripheral Component Interconnect) bus, and floppy disk drive 109 and keyboard/mouse 110 connected to M/B chip set 102 via a bridge circuit 108 and a slow bus such as ISA (Industry Standard Architecture) bus from the PCI bus. The computer exchanges data with another computer as transmitting terminal 10 or receiving terminal 20 by connecting to network 30 via network interface 106.

FIG. 2 is illustrative rather than limiting. Other configurations may be suitable as well. For example, the computer may be configured for processing image data in CPU 101 by mounting only a video memory instead of providing the video card 104, or may have a drive for CD-ROM (Compact Disc Read Only Memory) or DVD-ROM (Digital Versatile Disc Read Only Memory) via an interface such as ATA (AT Attachment).

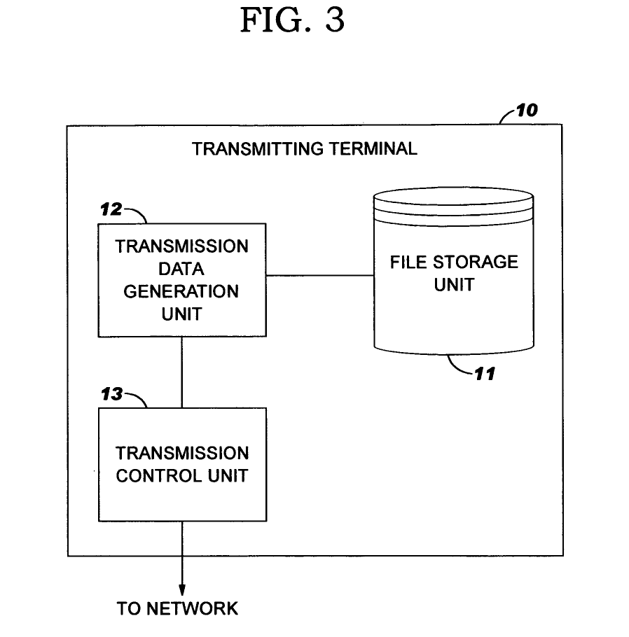

FIG. 3 is an exemplary diagram showing a functional configuration of the transmitting terminal 10. As shown in the figure, the transmitting terminal 10 includes a file storage unit 11 for storing a data file of original data to be transmitted, a transmission data generation unit 12 for generating transmission data from a data file stored in file storage unit 11, and a transmission control unit 13 for transmitting transmission data generated by transmission data generation unit 12 to receiving terminal 20. In this configuration, the file storage unit 11 is implemented by main memory 103 or hard disk 105 in the computer shown in FIG. 2, for example. Transmission data generation unit 12 and transmission control unit 13 are implemented by program controlled CPU 101.

A program for implementing the functions by controlling CPU 101 may be provided by storing and delivering on a magnetic disc, an optical disc, semiconductor memory, or other storage media, or by distributing over network 30. In the computer shown in FIG. 2, the program may be stored (installed) in hard disk 105, read into main memory 103, and expanded for controlling CPU 101 to function as transmission data generation unit 12 and transmission control unit 13.

Now, transmission data generation unit 12 will be described in more detail. Transmission data generation unit 12 first reads a data file of original data to be transmitted from file storage unit 11, and divides the data file into clusters, each of which has k blocks of data. Each block of data may be the same size. If the data is insufficient for completing a cluster, the data may be complemented according to an approach predetermined between transmitting terminal 10 and receiving terminal 20, for example by being padded with zeroes. Clusters or blocks of data of a cluster need not be in the same order as they are in the file. Transmission data generation unit 12 then generates parity data for each cluster by encoding original data of each cluster, and generates transmission data on the basis of the original data and the parity data.

Transmission data generation unit 12 encodes original data of a given cluster with dependence upon on another cluster through the use of convolution data

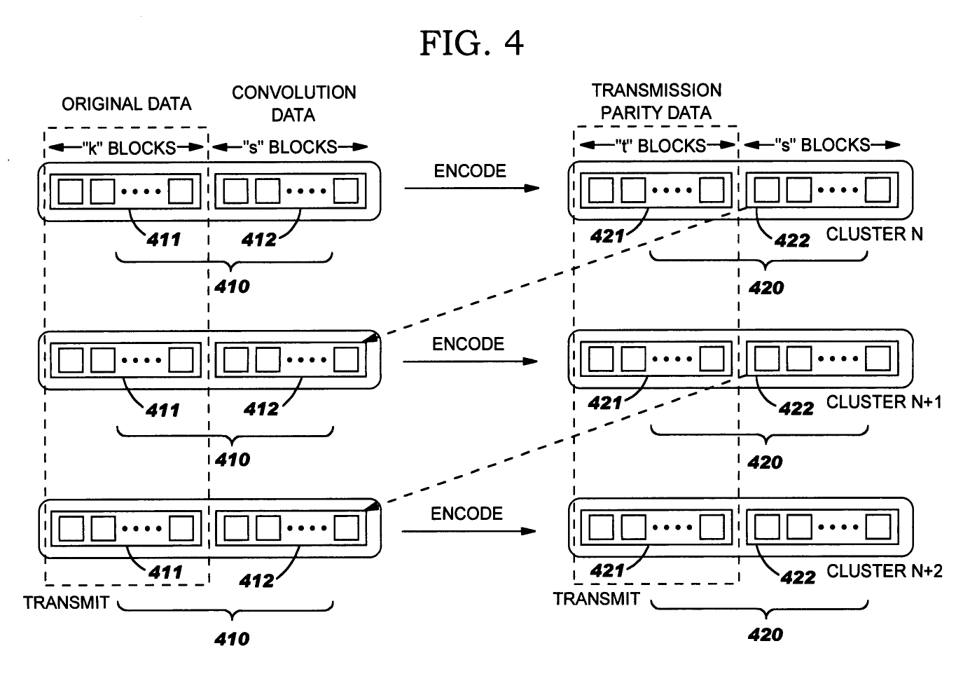

FIG. 4 is a illustrates a method of generating parity data. As shown in FIG. 4, the embodiment first adds s blocks of convolution data 412 to the original data 411. A data string 410 having k+s blocks of data is generated, where k is the number of blocks of original data 411.

Next, parity data 420 is generated by encoding the k+s blocks of the original data 411 and the convolution data 412. The blocks of data in the generated parity data 420 other than s blocks of data 422 are considered as parity data to be added to the original data, i.e., parity data to be transmitted with the original data (hereinafter referred to as transmission parity data 421).

The value of s will be less than or equal to t, where the number of blocks of transmission parity data 421 is t.

As shown in FIG. 4, s blocks of data 422 in the generated parity data 420 other than transmission parity data 421 become convolution data 412 for encoding the next cluster, where the term “next” refers to the order in which clusters are encoded, i.e., the encoding order. When a given cluster is encountered in its turn, s blocks of data 422 are acquired from parity data 420 in the preceding cluster and added to original data 411 as convolution data 412. In this manner, a cluster is encoded with dependence upon the preceding cluster. As the first cluster in an encoding order has no preceding cluster, predetermined blocks of data are provided to it as an initial value.

Transmission data generated by transmission data generating unit 12 in the above manner has k+t blocks of original data 411 and transmission parity data 421 for each cluster.

Transmission control unit 13 transmits transmission data generated in the above manner by controlling network interface 106 in the computer shown in FIG. 2, for example. Transmission data may be transmitted by specifying a destined receiving terminal 20 in the case of uni-cast, or may be transmitted without specifying a destination in the case of broadcast. Transmission need not be performed sequentially for each cluster. Blocks may be interleaved, for example, or parity data may be transmitted after the original data for all the clusters has been transmitted.

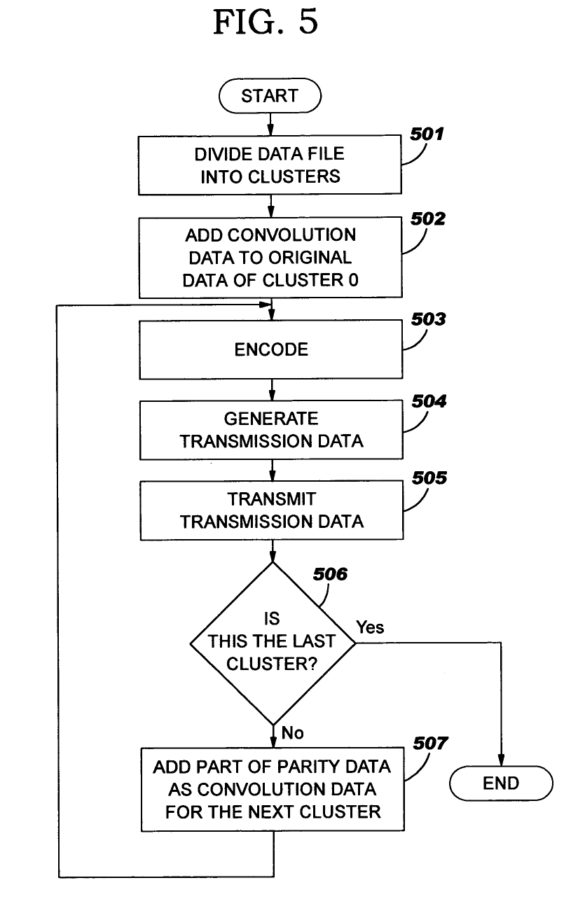

FIG. 5 is a flowchart illustrating aspects of the operation of transmitting terminal 10. The procedures shown in the figure are exemplary rather than limiting of the operation of transmitting terminal 10. As shown in FIG. 5, in transmitting terminal 10, transmission data generation unit 12 first divides a data file of original data read out from file storage unit 11 into clusters, each of which has k blocks (step 501). The clusters may be numbered sequentially from 0 according to the encoding order.

Next, transmission data generation unit 12 adds s blocks of convolution data, which may have predetermined initial values, to original data 411 in cluster 0 (the first cluster) (step 502). The data string of k+s blocks 410 is encoded to generate t+s blocks of parity data 420 (step 503). Then transmission data is generated (step 504). The transmission data includes the k blocks of original data 411 and t blocks of transmission parity data 421 of the parity data 420

Transmission control unit 13 transmits the transmission data of k blocks of original data 411 and t blocks of transmission parity data 421 (step 505). If the transmission data is the last cluster in the encoding order, data transmission ends (step 506).

Otherwise (i.e., a cluster remains to be processed), transmission data generation unit 12 then adds s blocks of data 422 of parity data 420 to the original data 411 of next the cluster as convolution data 412 (steps 506 and 507) and the operation returns to step 503 for repeating the processes in order.

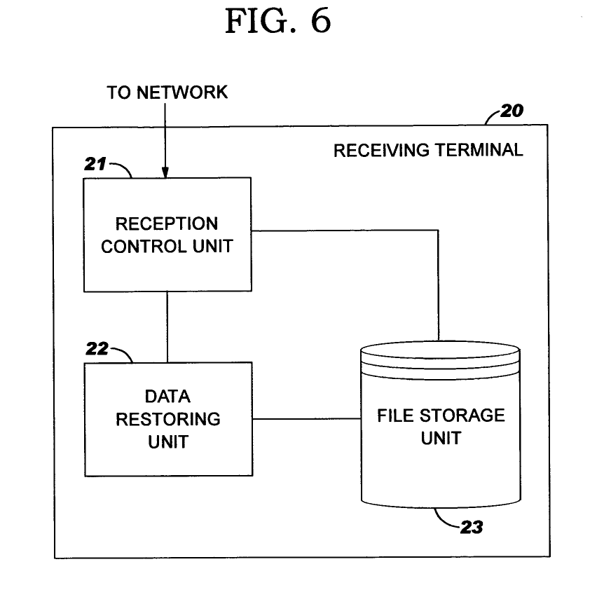

FIG. 6 is an exemplary diagram showing a functional configuration of receiving terminal 20. As shown in FIG. 6, receiving terminal 20 includes reception control unit 21 for receiving transmission data transmitted from transmitting terminal 10, data restoring unit 22 for restoring original data from received data received by reception control unit 21, and file storage unit 23 for storing a data file of original data received by reception control unit 21 or restored by data restoring unit 22. In this configuration, file storage unit 23 may be implemented by main memory 103 or hard disk 105 in the computer shown in FIG. 2, for example. Reception control unit 21 and data restoring unit 22 may be implemented in program controlled CPU 101.

A program for implementing the functions by controlling CPU 101 may be provided by storing and delivering on a magnetic disc, an optical disc, semiconductor memory, or other storage media, or by distributing over network 30. In the computer shown in FIG. 2, the program is stored (installed) in hard disk 105, read into main memory 103, and expanded for controlling CPU 101 to function as reception control unit 21 and data restoring unit 22.

Now, data restoring unit 22 will be described in more detail. If data transmitted from transmitting terminal 10 is received by receiving terminal 20 without any loss during communication, the received data includes the complete original data. Even if part of transmission data is lost, however, the original data can be restored by data restoring unit 22 when the loss is within certain limitations.

If part of original data is lost in a given cluster of received data received by reception control unit 21, data restoring unit 22 can acquire the original data by decoding the original data and parity data remaining in the cluster. The decoding is performed for each cluster. If only parity data is lost, decoding is not needed because the original data is intact.

Data restoring unit 22 uses convolution data of another cluster, if needed, to decode received data of a given cluster. Therefore, a cluster may need to be restored even though its original data has not been lost (i.e., only parity data is lost), so that the cluster can be used in restoring the next cluster.

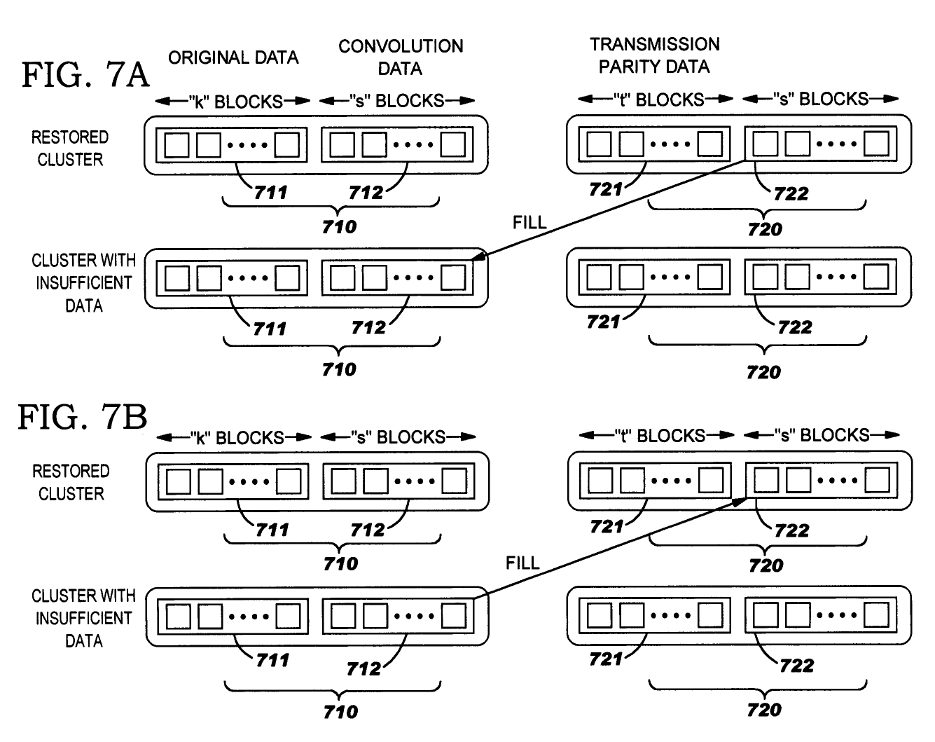

FIGS. 7A and 7B are diagrams illustrating a decoding method. As described above, t+s blocks of parity data (transmission parity data plus s blocks of data) are generated by encoding k+s blocks of original data and convolution data. Therefore, by decoding a given k+s blocks of the k+s+t+s blocks of data, the original data and convolution data can be restored. To do this, data restoring unit 22 first extracts k+s blocks of data from a cluster to be decoded, which are k blocks of original data plus s blocks of convolution data. Cluster data transmitted from transmitting terminal 10 is a string of k+t blocks as mentioned above, where s is less than or equal to t. Thus, unless t−s (i.e.,(k+t)−(k+s)) or more blocks are lost during communication, k+s blocks of data can be extracted.

Then the k+s blocks of data are decoded, and k blocks of original data 711 and s blocks of convolution data 712 are restored as shown in FIG. 7.

Now, the case will be considered wherein more than t-s blocks of received data of a given cluster are lost, resulting in the number of blocks of data being less than k+s. In this case, if original data or convolution data of the cluster immediately before or immediately after the cluster is restorable, the original data and the convolution data can be restored even for the given cluster (hereinafter referred to as a cluster of interest) by adding data from the cluster immediately before or immediately after. In other words, this case takes advantage of the equality of convolution data of a given cluster and s blocks of data other than transmission parity data in parity data of the cluster immediately before (see FIG. 4).

With reference to FIG. 7A, a case will be described wherein original data and convolution data can be restored for the cluster immediately before a cluster of interest. In this case, by encoding restored data of the cluster immediately before (the number of blocks of data is k+s) in the same manner as in transmission data generation unit 12 in transmitting terminal 10, the same parity data 720 can be generated as the parity data 420 generated by transmission data generation unit 12. In other words, s blocks of data 722 other than a part corresponding to transmission parity data 421 in the parity data 720 are the same as the convolution data 712 of the cluster of interest.

Then parity data 720 is generated by encoding restored data in the cluster immediately before, and k+s blocks of data of a cluster of interest are complemented by adding, to the cluster of interest, the required number of blocks of data (filling data) from part of the s blocks of data 722. In this manner, the original data 711 and convolution data 712 are restored for the cluster of interest.

Next, referring to FIG. 7B, a case will be described wherein the original data and convolution data can be restored for the cluster immediately after a cluster of interest. In this case, convolution data 712 of the cluster immediately after is the same as data of the cluster of interest 722. The k+s blocks of data of the cluster of interest are complemented by adding the required number of blocks of data (filling data) from the restored convolution data 712 of the cluster immediately after the cluster of interest. In this manner, the original data 711 and convolution data 712 are restored for the cluster of interest.

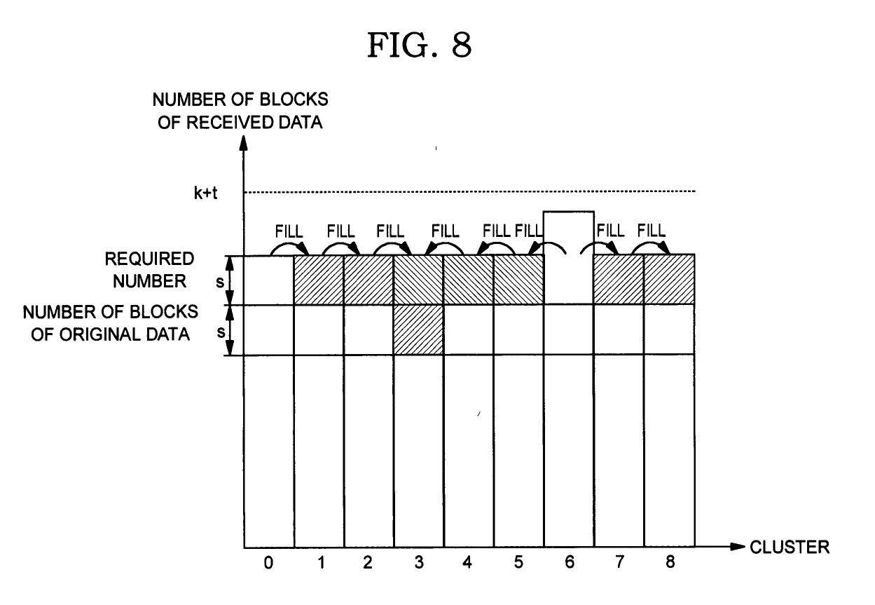

FIG. 8 is a diagram showing how data may be complemented by using a decoded cluster as described above. As shown in FIG. 8, the number of blocks of received data required for restoring the original data and convolution data of a cluster (k+s blocks) is considered as the required number (the largest number of blocks of received data is k+t). In the example shown in FIG. 8, cluster 0 and cluster 6 have received the required number of blocks of data, or more. Thus, each of these clusters can restore the original data and convolution data on its own.

The number of blocks of received data for each of clusters 1 and 2 is equal to the number of blocks of original data, which is insufficient for restoration. By sequentially acquiring filling data from the restored data in cluster 0 and complementing, the original data and convolution data can be restored. The number of blocks of received data for each of clusters 4, 5, 7 and 8 is equal to the number of blocks of original data, which is also insufficient. By sequentially acquiring filling data from the restored data of cluster 6 and complementing, the original data and convolution data can be restored.

The number of blocks of received data of cluster 3 is less than the number of blocks of original data by s blocks, which is less than the required number by 2s blocks. As the original data and convolution data of clusters 2 and 4 are restored in the above-mentioned manner, the original data and the convolution data of cluster 3 can be restored even in this case by acquiring s blocks of filling data from each of the restored data and complementing.

Therefore, for a cluster to restore the original data, the number of blocks of data needed is the sum of the number of blocks of original data and the number of blocks of convolution data. With at least one such cluster (a cluster received through good communication), original data can be restored by using data restored from the cluster if the number of blocks of data equal to that of original data can be received in another cluster. Original data can be partly restored even if the number of blocks of received data is less than that of original data in some clusters.

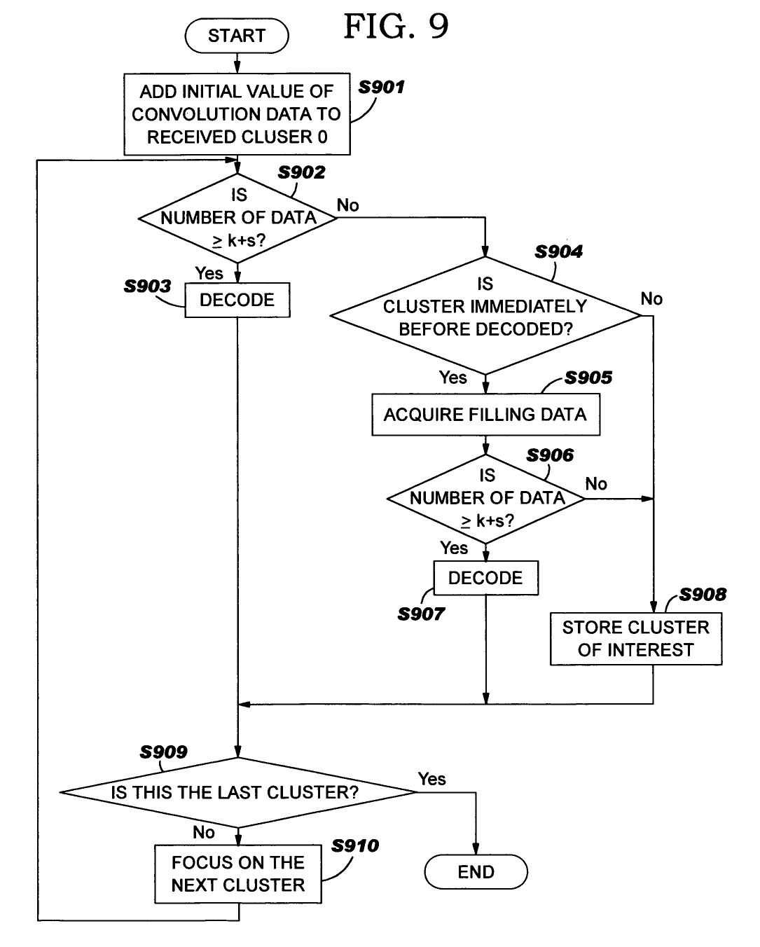

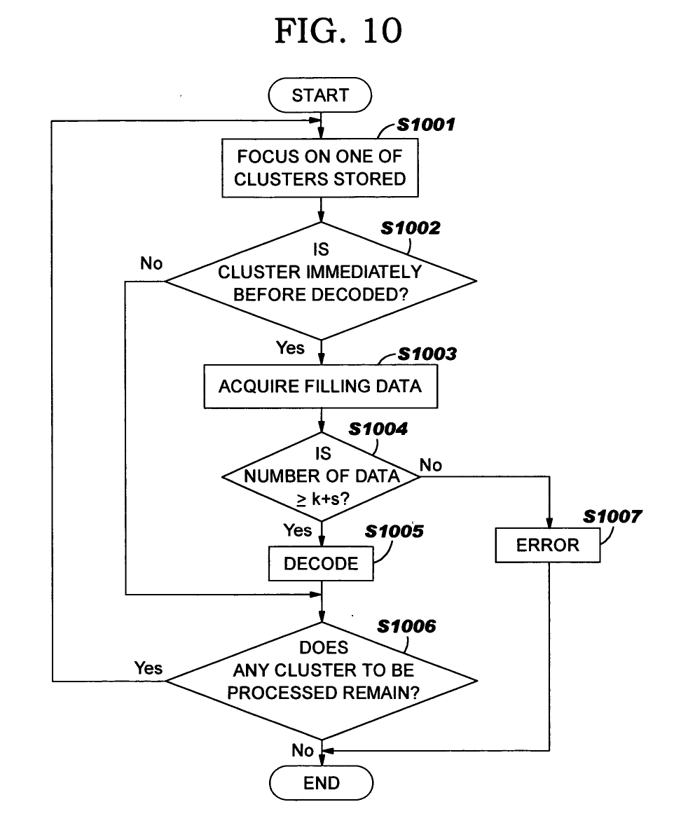

FIGS. 9 and 10 are flowcharts that illustrate the restoration of original data by data restoring unit 22 of receiving terminal 20. The procedures shown are exemplary operations by receiving terminal 20, and are not intended to be limiting of the present invention.

Data transmitted from transmitting terminal 10 is received by reception control unit 21. Data restoring unit 22 first restores original data by decoding clusters in order as shown in FIG. 9. The procedures shown in FIG. 10 attempt to restore a cluster that cannot be restored in this manner.

As shown in FIG. 9, data restoring unit 22 considers cluster 0, which is the first cluster received by reception control unit 21, as a cluster of interest, and adds s blocks of convolution data 712, which has predetermined initial values, to the received data (step 901). The initial value may be the same as that of convolution data 412 to be added to original data 411 in generating parity data of cluster 0. The initial values for each of convolution data 412 and 712 can be shared by a plurality of transmitting terminals 10 and receiving terminals 20 connected to network 30, so that the initial values can be added without loss during communication. It is also possible to check whether the number of blocks of received data of cluster 0 is sufficient for restoring original data (k+s blocks) at first, and to add an initial value of convolution data 712 only if the number of blocks of received data is less than the required number.

Then the number of blocks of data of cluster 0, to which an initial value of convolution data 712 is added, is checked to determine whether it is at least the required number of k+s blocks. If the number of blocks of data is at least k+s, cluster 0 is decoded and original data 711 is acquired (steps 902 and 903).

If the number of blocks of data of cluster 0 is less than k+s, data restoring unit 22 checks whether the cluster immediately before is decoded or not. As cluster 0 has no cluster before, data restoring unit 22 determines that the cluster immediately before is not decoded and temporally stores cluster 0 in a storage device (for example, in main memory 103 shown in FIG. 2) (steps 904 and 908).

After cluster 0 can be decoded at step 903 or after cluster 0 is stored at step 908, the cluster of interest is checked to determine whether it is the last cluster or not. If the cluster of interest has a next cluster, the next cluster becomes the new cluster of interest, and the operation returns to step 902 (steps 909 and 910).

In the same manner, the new cluster of interest is checked to determine whether the number of blocks of received data is at least k+s. If the number is at least k+s, the cluster of interest is decoded, and original data 711 and convolution data 712 are acquired (steps 902 and 903).

If the number of blocks of received data of the cluster of interest is less than k+s, then data restoring unit 22 checks whether or not the cluster immediately before is decoded (step 904). If the cluster immediately before is decoded, blocks of data 722 up to s blocks from parity data 720 are acquired, resulting from encoding the restored data of the cluster immediately before, as filling data, and the cluster of interest is filled (step 905). Thereafter, the number of blocks of data of the cluster of interest filled with data is checked again to determine whether that number is at least k+s. If the number is at least k+s, meaning that the data is complemented, the cluster of interest is decoded and original data 711 and convolution data 712 are acquired (steps 906 and 907).

If it is determined that the cluster immediately before is not decoded at step 904, or the number of blocks of data of the cluster of interest is less than k+s even after filled from the cluster immediately before, the cluster of interest is temporarily stored (for example, in main memory 103 shown in FIG. 2) (step 908).

After the cluster of interest can be decoded at step 903 or 907, or after the cluster of interest is stored at step 908, the cluster of interest is checked to determine whether it is the last cluster. If the cluster has a next cluster, the next cluster becomes the new cluster of interest, and the operation returns to step 902 (steps 909 and 910). If the cluster of interest is the last cluster, data restoring unit 22 performs the processes according to FIG. 10 for a cluster stored at step 908 (to be decoded).

As shown in FIG. 10, data restoring unit 22 focuses on one of the clusters stored in storage device (step 1001) and checks whether or not the cluster immediately after the cluster of interest is decoded (step 1002). If the cluster immediately after is decoded, the decoded convolution data 712 is acquired as filling data (step 1003). The number of blocks of data of the cluster of interest filled with data is checked again to determine whether it is at least k+s. If the number is at least k+s, meaning that the data is complemented, the cluster of interest is decoded, and original data 711 and convolution data 712 are acquired (steps 1004 and 1005).

The above-mentioned processes are repeated until no cluster remains to be processed in the storage device (step 1006). If the number of blocks of data is less than k+s of the cluster of interest even after filled with data from the cluster immediately after, meaning that the cluster of interest cannot be further filled, an error process is performed (such as outputting an error message) and the operation ends (step 1007).

In the above-mentioned operation, if it is determined that the cluster immediately after is not decoded at step 1002, the cluster of interest is not decoded in the cycle concerned. The cluster is decoded when it becomes the cluster of interest again after clusters to be processed are sequentially subject to the above-mentioned operations and the clusters following the cluster of interest are decoded. As shown in FIG. 10, filling with data from the cluster immediately after, in reverse order of clusters received, eliminates the problem, in that data is prevented from filling by the fact that the cluster immediately after is not yet processed (in this case, if it is determined that the cluster immediately after is not decoded, meaning the cluster of interest cannot be filled with data, an error process is performed and the operation ends).

The above-mentioned procedure is exemplary rather than limiting, and data can be restored in other ways. For example, a procedure is possible that first restores original data 711 and convolution data 712 for a cluster including k+s blocks of data, and then restores for a cluster including less than k+s blocks of data by filling data from the cluster before or after.

Another procedure is possible wherein the number of blocks of original data or parity data is checked for each received cluster, on the basis of a positional relationship between a cluster having at least the number of blocks of data number and a cluster lacking the required number and the number of blocks of data to be filled for each cluster. A determination is made of which cluster provides how many blocks of data to the cluster before or after and the order of decoding/encoding. Encoding/decoding is then performed in the determined order; blocks of data required for filling the cluster that lacks the required number of blocks are acquired; and the original data of the cluster is restored.

In determining the order of decoding/encoding, the computational load of encoding/decoding and disk I/O can be taken into consideration. For example, if the number of blocks of received data of a given cluster and clusters before and after the cluster concerned meets the required number, convolution data 712 need not be restored in the given cluster, leaving original data 711 to be restored. If the cluster before lacks one block of received data for the required number, one block of convolution data 712 is restored in the given cluster. If the number of blocks of received data of a given cluster is less than the required number, and the number of blocks of received data of the cluster before or after meets the required number, data 722 from parity data 720 is acquired with less effort than acquiring convolution data 712. Thus, data to be filled is acquired from convolution data 712 in the cluster after.

The original data restored by data restoring unit 22 in the above-mentioned manner (and original data received by reception control unit 21) 711 is an original data file divided into clusters by transmitting terminal 10. Therefore, the original data is concatenated by inverse transformation of the process of dividing the original data into clusters, and finally the same data file as that read out from file storage unit 11 in transmitting terminal 10 is restored and stored in file storage unit 23.

As mentioned above, parity data is generated by adding data (parity data) of another cluster to original data and encoding. The parity data is transmitted with original data for each cluster. Therefore, even if blocks of received data are lost, resulting in an insufficient number of blocks for restoring original data, the original data can be restored by filling with data from another involved cluster.

With this approach, original data can be restored even if the number of blocks of received data is less than the number of blocks of original data due to data loss during communication, and the probability of reception success can be improved in systems using FEC (Forward Error Correction). From another perspective, this means that the number of blocks of parity data can be reduced for a given probability of reception success.

In generating transmission data, s blocks of data 422 other than transmission parity data 421 in parity data 420 in a given cluster are added to original data of the next cluster (see FIG. 4). Therefore, at receiving terminal 20, the last cluster cannot be filled with data from the subsequent cluster. In other words, the probability of reception success decreases only for the last cluster.

For the last cluster, s blocks of data 422 other than transmission parity data 421 in parity data 420 are transmitted with transmission data including k+t blocks of original data 411 and parity data 421. In this manner, the same filling data as that for another cluster is provided for the last cluster. Only for the last cluster, in order to transmit s blocks of data 422, a data string made of k+t+s blocks of data, which is the sum of whole blocks of parity data 420 and original data 411, can be transmitted, or s blocks of data 422 other than transmission parity data 421 can be transmitted separately. All of the s blocks of data are not necessarily transmitted. Transmission data can be generated by adding t′ blocks of data, where t′ is greater than t, to the above-mentioned original data and transmitted.

Information for identifying the arranged order, the first cluster, the last cluster, or the like corresponding to the original data file of each cluster may be described in a header or the like of a packet when each cluster is transmitted, allowing determination based on descriptions in the packet header by receiving terminal 20.

As mentioned above, the present invention can improve the probability of distribution success for higher reliability of data communication systems with FEC. According to the present invention, redundancy in data communication with FEC can also be reduced.

I claim:

1. A method for transmitting and receiving data between terminal devices on a network, comprising the steps of:
dividing a data file of original data to be transmitted into clusters each having k blocks of data;
generating t+s blocks of parity data for a cluster by encoding s blocks of convolution data and k blocks of original data;
generating k+t blocks of transmission data using the k blocks of original data and t blocks selected from the parity data; and
transmitting the transmission data to another terminal on the network.

2. The method according to claim 1, wherein the convolution data for a first cluster is generated using data from a second cluster.

3. The method according to claim 1, wherein transmission data is generated by adding, to the original data of the cluster, t′ blocks of data from the t+s blocks of parity data, where t′>t.

4. A method for transmitting and receiving data between terminal devices on a network, comprising the steps of:
dividing a data file of original data to be transmitted into clusters;
generating parity data for a first cluster by encoding original data of the first cluster using information from a second cluster;
generating transmission data by adding the parity data to the original data; and
transmitting the transmission data to another terminal on the network.

5. The method according to claim 4, wherein the parity data is generated by encoding the original data using data selected from parity data of the second cluster.

6. The method according to claim 4, wherein at least part of the parity data of the first cluster is added to original data of the second cluster when original data of the second cluster is encoded.

7. A method for transmitting and receiving data between terminals on a network, comprising the steps of:
receiving a data string including original data divided into clusters and parity data;
if data of a given cluster is lost during communication, decoding remaining data of the given cluster and restoring original data of the given cluster and convolution data used to generate parity data for the given cluster;
unless the number of blocks of data in the given cluster is sufficient to restore the original data and the convolution data, complementing and decoding data of the given cluster using restored data of another cluster, and restoring the original data and the convolution data; and
generating a data file by concatenating the original data of the clusters.

8. The method according to claim 7, wherein, unless the number of received blocks of data of the given cluster is sufficient to restore the original data and the convolution data, data of the given cluster is complemented using data acquired by encoding original data and convolution data restored in a cluster immediately before or immediately after the given cluster.

9. A communication system for exchanging data between terminal devices via a network, comprising:
a transmitting terminal device that divides a data file of original data into clusters,
generates parity data for a cluster by encoding data in the cluster using data in a second cluster, and transmits, over a network, transmission data generated by adding the parity data to original data of the cluster; and
a receiving terminal device that receives the transmission data transmitted by the transmitting terminal device and restores the original data for the cluster if part of the transmission data is lost during communication.

10. The communication system according to claim 9, wherein, unless the number of blocks of received transmission data of the cluster is sufficient to restore original data lost during communication, the receiving terminal device complements the cluster using restored data of the second cluster and restores the original data of the cluster.

11. A data transmitting device for transmitting data via a network, comprising:
a file storage unit for storing a data file of original data;
a transmission data generation unit for reading original data from the file storage unit, dividing the read original data into clusters, generating parity data for a cluster by encoding original data of the cluster using data of a second cluster, and generating transmission data including the parity data and the original data; and
a transmission control unit for transmitting the transmission data generated by the transmission data generation unit.

12. The data transmitting device according to claim 11, wherein the transmission data generation unit uses parity data of a cluster immediately before the cluster when encoding original data of the cluster.

13. A data receiving device for receiving data transmitted via a network, comprising:
a reception control unit for receiving a data string including original data divided into clusters and parity data;
a data restoring unit which, if any data is lost in a cluster during communication, decodes remaining data in the cluster and restores the original data and convolution data used for generating parity data for the original data, and which, unless the number of blocks of data received is sufficient to restore the original data and the convolution data, complements and decodes the cluster using restored data of a second cluster to restore the original data and the convolution data; and
a file storage unit for storing a data file obtained by concatenating the received or restored original data.

14. The data receiving device according to claim 13, wherein, unless the number of received blocks of data of the cluster is sufficient to restore the original data and the convolution data, the data restoring unit complements the given cluster using data acquired by encoding the original data and convolution data restored in the cluster immediately before the cluster or convolution data restored in the cluster immediately after the cluster.

15. A program product for transmitting data by controlling a computer connected to a network to enable the computer to execute method steps comprising:
dividing a data file of original data to be transmitted into clusters each of which has k blocks of data;
generating t+s blocks of parity data for a cluster by encoding the k blocks of original data of the cluster using s blocks of convolution data;
generating k+t blocks of transmission data by adding t blocks selected from the parity data to the original data of the cluster; and
transmitting the transmission data via the network.

16. The program product according to claim 15, wherein the s blocks of convolution data for the cluster are selected from parity data of a second cluster immediately before the cluster.

17. A program product for receiving data transmitted via a network by controlling a computer connected to the network to enable the computer to execute method steps comprising:
receiving a data string including original data divided into clusters and parity data;
decoding remaining data in a cluster and restoring original data of the cluster and convolution data used to generate parity data for the given if any data of the cluster is lost during communication;
complementing and decoding data of the cluster using restored data of a second cluster and restoring the original data and the convolution data unless the number of blocks of received data is sufficient to restore the original data and the convolution data; and
generating a data file by concatenating the original data of the received or restored clusters.

18. The program product according to claim 17, wherein the cluster is complemented using data acquired by encoding the original data using convolution data restored in a second cluster immediately before the cluster or using convolution data restored in a third cluster immediately after the cluster.
